(19) United States
(12) Patent Application Publication
(10) Pub. No.: US 2014/0252239 A1
(43) Pub. Date: Sep. 11, 2014

(54) DIGITAL X-RAY IMAGE SENSOR DRIVE

(71) Applicants: Buon Nguyen, Milpitas, CA (US); Uwe Zeller, Biberach (DE)

(72) Inventors: Buon Nguyen, Milpitas, CA (US); Uwe Zeller, Biberach (DE)

(73) Assignee: FORSTGARTEN INTERNATIONAL HOLDING GMBH, St. Gallen (CH)

(21) Appl. No.: 14/126,800

(22) PCT Filed: Jun. 18, 2012
(86) PCT No.: PCT/US2012/042886

§ 371 Date: May 7, 2014

Related U.S. Application Data
(60) Provisional application No. 61/497,637, filed on Jun. 16, 2011.

(51) Int. Cl. H01L 27/146

(52) U.S. Cl. CPC H01L 27/14663
USPC 250/366; 257/428

(57) ABSTRACT

A digital X-ray image sensor device comprising a fibre-optic scintillating layer for converting X-rays into optical radiation and a photoelectric conversion layer for converting the optical radiation into electrical signals, the photoelectric conversion layer comprising an array of CMOS sensor elements, wherein each of the sensor elements has a composite exposure response characteristic comprising a low exposure region characterized by a first gain and a high exposure region characterized by a second gain, wherein the first gain is higher than the second gain.

### BACKGROUND

The present invention relates to X-ray imaging, including dental X-ray imaging. More specifically, the invention relates to a digital X-ray image sensor device comprising a layer, in particular a scintillating layer, in particular a fibre-optic scintillating layer, for converting X-rays into optical radiation and a photoelectric conversion layer for converting the optical radiation into electrical signals, the photoelectric conversion layer comprising an array of CMOS sensor elements or pixels.

Herein, the term “scintillating layer” means any element which converts X-ray radiation into optical radiation, i.e. radiation in the visible, UV or near IR portion of the electromagnetic spectrum, irrespective of the detailed structure and composition thereof. In particular, the term covers prior art elements which consist of a fibre optic plate and a scintillating layer provided thereon. The term “conversion layer” designates any photoelectrical converter for converting the optical radiation generated in the scintillating layer into electrical signals on a pixel-basis, i.e. comprising an array of photoelectric converter or sensor elements, respectively, of the CMOS type. In particular, the term covers integrated arrays of CMOS sensor elements in a silicon or other semiconductor substrate. However, it is not limited to such silicon die sensor devices but likewise covers devices manufactured in thin film or hybrid technology and others.

Such digital X-ray sensors are an established modality in medical and more specifically in dental imaging.

The basic operating principle is to use an electronic detector with a size similar to dental X-ray films, such detector being capable to quantize the latent X-ray image in space (e.g. into pixels) and assess the X-ray dose with corresponding resolution, e.g. within such pixels. Known sensors use a linear dose-output signal behaviour, which works well until an upper dose limit is reached and the output signal (e.g. pixel-based) is clipped. This point is in the field normally denominated as saturation.

This known design is causing the constraint that sensors which are designed for a good signal to noise ratio (SNR), at low dose reach saturation too early, or that sensors optimized for a high dose rate will have a less than the desired SNR at low dose levels.

In principle, it is known in the field of imaging to provide a solution to this problem by using sensors with a logarithmic response; see e.g. N. Ricquier, B. Dierickx: “Pixel Structure with Logarithmic Response for Intelligent and Flexible Imager Architectures”, Microelectronic Engineering 19 (1992), 631-634.

A further constraint for such pixel designs, is the so-called fill-factor. Specifically for diagnostic X-ray imaging, systems need to be designed such that the dose used is as low as reasonable achievable (the so-called “ALARA principle”). This constraint results in the requirement that the sensitive surface should be optimized. The surface in a semiconductor imager is basically the extension of the charge collection structure, i.e. adding more transistors and/or connections typically decreases this parameter and is, therefore, a drawback.

A further constraint for an electronic detector used for digital/x-ray imaging is the inherent variation in the individual response of a pixel, which are statistically distributed around a mean/average value and the small likelihood that pixels or groups of pixels are not working as specified (so called blemishes). This constraint is known to the expert and typically addressed by a correction matrix which assigns each pixel a specific gain correction value and characterising the distribution of blemishes by a defect map.

### SUMMARY OF THE INVENTION

One challenge associated with image sensors having a logarithmic response is that the design thereof is more complicated and the implementation of a precise response characteristic in manufacturing processes is quite difficult.

It is an object of the invention to provide a digital X-ray image sensor comprising sensor elements, in particular CMOS sensor elements, which has an improved response characteristics over sensors of the linear type, without heavily complicating sensor design and manufacturing.

This object is solved by a digital X-ray image sensor according to claim 1. Embodiments of the invention are subject of the dependent claims.

It is an aspect of the invention, that each of the sensor elements has a composite exposure response characteristic comprising a low exposure region characterized by a first gain and a high exposure region characterized by a second gain, wherein the first gain is higher than the second gain.

In an embodiment of the invention, in the low exposure region and/or in the high exposure region the gain slope of the sensor elements is linear. More specifically, the gain slope is linear both in the low and high exposure regions. In further embodiments, the ratio between the high gain and the low gain is 2 or higher, preferably 4 or higher. Such “two-step linear” response characteristic can be implemented with limited modifications of the sensor element circuitry but provides, at the same time, for a clearly improved sensor behaviour with a wide range of X-ray machine types and X-ray doses used, e.g. in medical and, more specifically, dental imaging applications. It provides a low noise video output that results in sharper and cleaner images, both at low and high X-ray dose.

Under the aspect of important applications as mentioned above, in a further embodiment the maximum X-ray exposure, determined under standard conditions, is between 1000 and 1500 μGy, preferably between 1200 and 1300 μGy. In a further embodiment, related to such specific adjustment of the sensor characteristic, a transition point between the low exposure region and the high exposure region of the response characteristic is, in terms of X-ray exposure determined under standard conditions, between 400 and 600 μGy, preferably between 450 and 500 μGy.

In many fields of application a further embodiment can be useful, wherein the location of a transition point between the low exposure region and the high exposure region of the response characteristic on an X-ray exposure scale is electrically controllable and an external transition point control input and internal transition point control bus are provided.

In a further embodiment of the invention, which is easy to design and to manufacture, the sensor elements each comprise a four-transistor-one-diode circuit structure, wherein one of the four transistors and a capacitor, which is added to the inherent capacitance of the photo diode, are dedicated to implementing the lower gain response in the high exposure region. In accordance with an embodiment mentioned further above, in such circuitry each of the sensor elements comprises a transition point control input, connected to a gate of the dedicated transistor. Such design can still maintain a high fill factor and use a minimum current of less than 10 mA, and it minimizes the added components in the pixel side, for the benefit of high yield and uniformity of pixel-to-pixel response. However, the invention is not limited to such design but can also be implemented with more than just one additional capacitor and/or associated additional switching elements (transistor).

In a further embodiment, the sensor device of the invention comprises a fabrication parameter memory and calibration means connected to the fabrication parameter memory, for reducing fixed-pattern noise of the sensor elements by fabrication parameter based sensor calibration. Namely, it is beneficial to characterize the actual shift point for each pixel at the time of manufacturing, as well as the impact of secondary effects, and to provide this information as a correction model which allows calculating a hypothetical linear response of the pixels. For simplification, it can, in a more specific embodiment, be sufficient to store a model which calculates the transition point (which can also be called “knee point” or “bending point”) and smoothing factors around this point. A correction model can be defined, based on the first gain, the knee point characteristic and the second gain, such correction model is used to provide fixed pattern noise compensation.

Alternatively, the sensor fabrication parameters can be stored independently and/or remotely from the sensor and are used for sensor calibration which reduces fixed-pattern noise or which in particular reduces fixed-pattern noise.

In a further embodiment, which utilizes well-known manufacturing techniques in electronics, the array of sensor elements is formed as an integrated circuit in a plate-shaped silicon substrate which is bonded to a fibre-optic scintillating plate and to a PCB and encapsulated in a housing, to form a plate-shaped X-ray image sensor. This embodiment can be denominated as a sensor of the silicon die type and can, more specifically, be embodied as an improved dental imaging sensor.

### BRIEF DESCRIPTION OF THE DRAWINGS

FIG. 1 is a graph of the output voltage of a CMOS pixel of an embodiment of the invention vs. the X-ray dose, compared to the pixel response characteristics of two conventional sensors.

FIG. 2 is a circuit diagram of a CMOS pixel of an embodiment of the sensor device according to the invention.

FIGS. 3A and 3B schematically illustrate an embodiment of the respective pixel layout of an embodiment of the invention vs. a conventional pixel layout.

### DETAILED DESCRIPTION

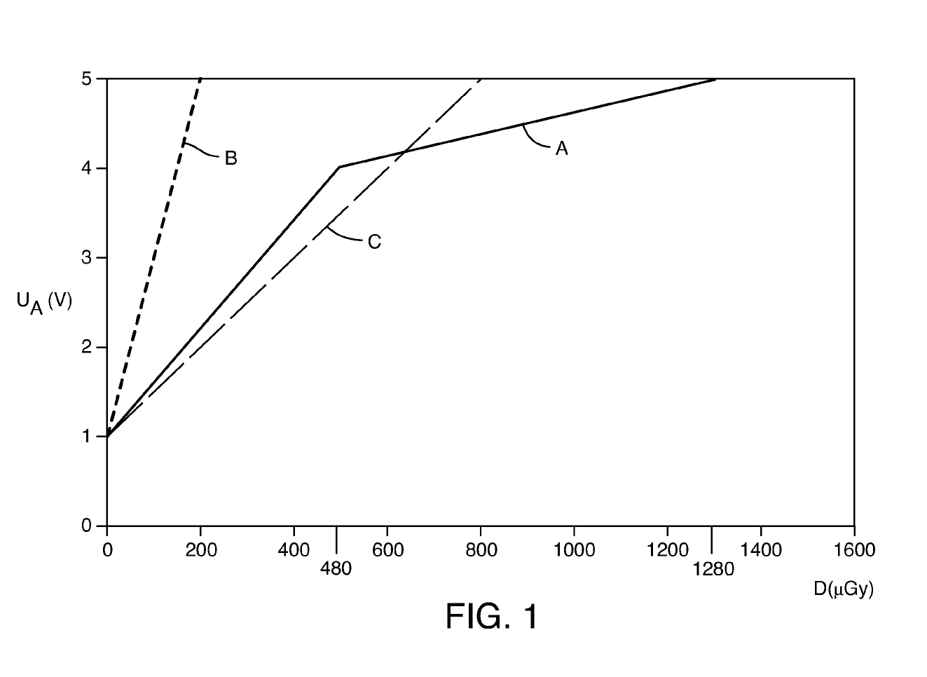

FIG. 1 shows, in a graph of the output voltage U_{A} of a CMOS pixel (in volts) vs. the X-ray dose D (in μGy), the response characteristic of an X-ray sensor device according to the invention (curve A), compared to the response characteristics of two conventional linear response sensor devices (curve B and curve C). The figure clearly shows that the sensor element has a composite exposure response characteristic comprising a low exposure region A1 characterized by a first gain and a high exposure region A2 characterized by a second gain, wherein the first gain is higher than the second gain. Herein, the specific parameter values both of the X and Y axis are exemplary and can be different in other embodiments, depending on the specific sensor design and (as explained in more detail further below) on a DC control voltage for setting the transition point. Even the shape of curve A is exemplary and can be different in modified embodiments, e.g. in having a more smooth transition portion between the low and high exposure regions.

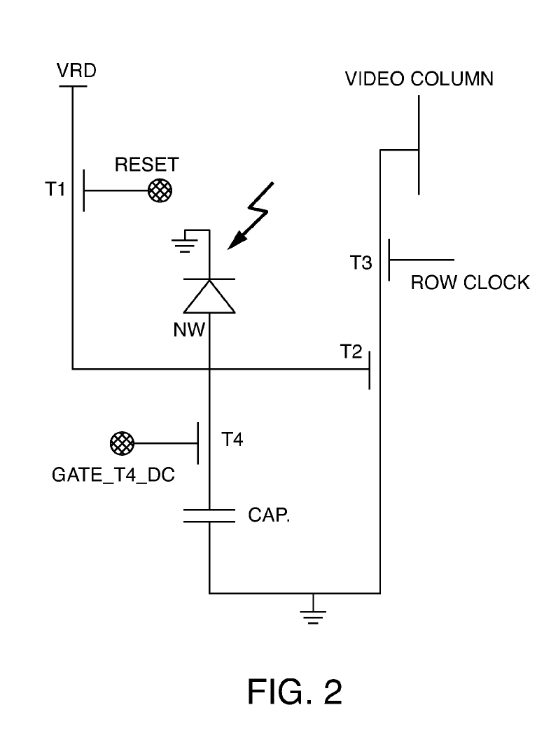

FIG. 2 is a schematic block diagram of a sensor pixel of a sensor device in an embodiment of the invention, having a four-transistor switching arrangement T1, T2, T3, T4 associated to a photo diode NW and an additional capacitor CAP for linear low gain response at high X-ray exposure. Whereas transistors T1, T2, and T3 are switching elements of a conventional linear response CMOS sensor pixel, transistor T4 has been added for switching the capacitor CAP.

In a conventional sensor design comprising the photo diode WN and transistors T1 to T3, diode WN is reset to a reset voltage through transistor T1 before starting sensing, i.e. collecting photons. The collected photons will reduce the reset voltage of diode WN, which in turn reduces the conducting current of sensing transistor T2. T3 is just a row switching transistor for turning sensor rows sequentially in a video sequence. The conducting current change in transistor T2 will be converted to a voltage change at an output amplifier and provides a single gain linear response at pixel level.

When photons are being collected to a accumulation point when the voltage between the gate of T4 and the source of T4 (connected to the photo diode WN) is higher than the threshold voltage of T4, this additional transistor is turned on and the capacitance of the additional capacitor CAP adds to the capacitance (conventional “capacitor”) of photo diode WN. Thus, “combined capacitor” with increased capacitance reduces the gain of the pixel, due to the fact that more photons are needed to discharge the capacitor. Insofar, adding the capacitance of capacitor CAP provides the result that the response characteristic transitions to the second region, i.e. the region of lower gain at higher exposure (region A2 of curve A in FIG. 1). In other words: Once the additional switching transistor T4 is activated, the charge generated by incident photons is “split” between transistors T2 and T4, resulting in the decreased slope of the output characteristic in its high exposure region.

For controlling the position of the transition point between regions A1 and A2 in the relevant response curve A in FIG. 1, a DC control line GATE_T4_DC is provided at pixel level, at the additional transistor T4.

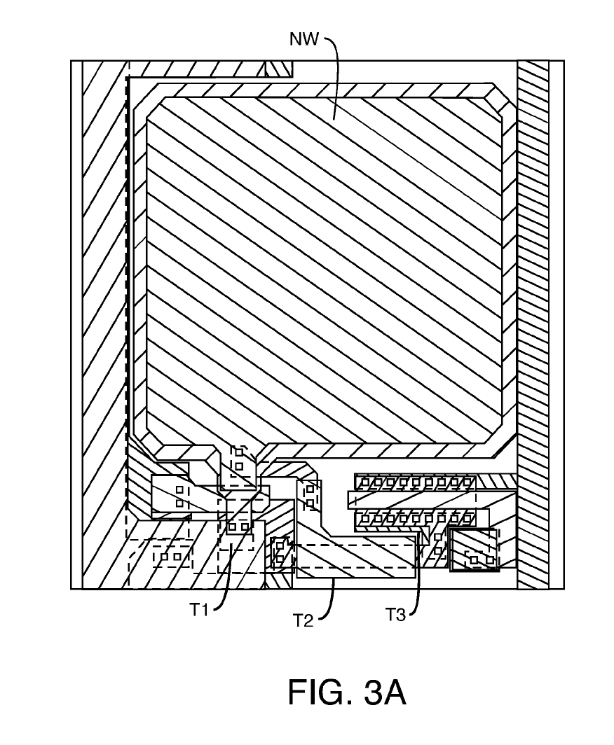

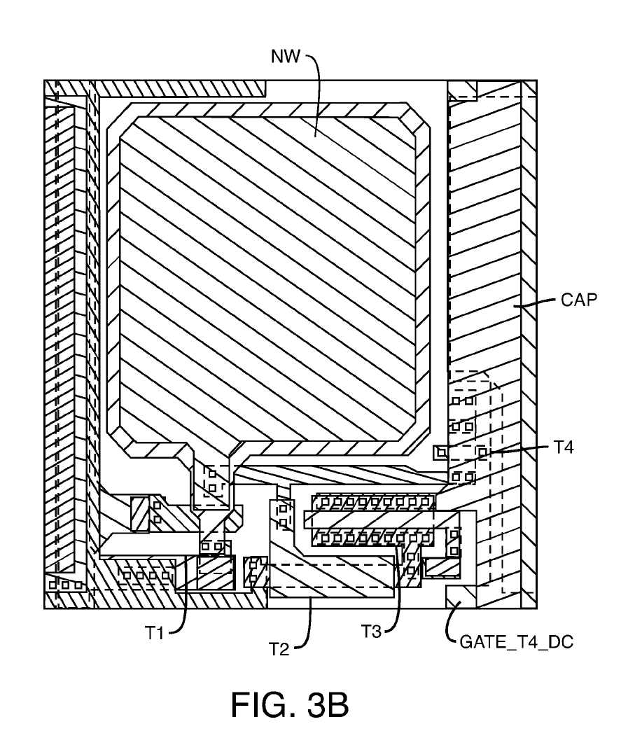

FIGS. 3A and 3B are comparative schematic illustrations of relevant layers of the layout of a conventional three-transistor pixel structure (FIG. 3A) and the embodiment explained above, i.e. the four-transistor structure with the additional capacitor (FIG. 3B). Reference numerals T1, T2, T3, T4, WN, CAP and GATE_T4_DC are the same as in FIG. 2 and explained above. It is to be noted that in both layer diagrams many layers are omitted, for the sake of highlighting the relevant elements. From a comparison of both figures, it can be recognized that the design modifications of the inventive embodiment with respect to the conventional design are limited, and so are the required modifications of the manufacturing process.

Various features and advantages of the invention are set forth in the following claims.

1. A digital X-ray image sensor device comprising a layer for converting X-rays into optical radiation and a photoelectric conversion layer for converting the optical radiation into electrical signals,
the photoelectric conversion layer comprising an array of sensor elements, wherein each of the sensor elements has a composite exposure response characteristic comprising a low exposure region characterized by a first gain and a high exposure region characterized by a second gain, wherein the first gain is higher than the second gain.

2. The sensor device of claim 1, wherein the sensor elements are CMOS sensor elements.

3. The sensor device of claim 1, wherein in the low exposure region and/or in the high exposure region the gain slope of the sensor elements is linear.

4. The sensor device of claim 3, wherein the gain slope is linear both in the low and high exposure regions, and the ratio between the high gain and the low gain is 2 or higher, preferably 4 or higher.

5. The sensor device of claim 1, wherein the maximum X-ray exposure, detelmined under standard conditions, is between 1000 and 1500 μGy, preferably between 1200 and 1300 μGy.

6. The sensor device of claim 1, wherein a transition point between the low exposure region and the high exposure region of the response characteristic is, in terms of X-ray exposure determined under standard conditions, between 400 and 600 μGy, preferably between 450 and 500 μGy.

7. The sensor device of claim 1, wherein the location of a transition point between the low exposure region and the high exposure region of the response characteristic on an X-ray exposure scale is electrically controllable and an external transition point control input and internal transition point control bus are provided.

8. The sensor device of claim 1, wherein the sensor elements each comprise a four-transistor-one-diode circuit structure and a capacitor, wherein one of the four transistors and the capacitor are dedicated to implementing the lower gain response in the high exposure region.

9. The sensor device of claim 7, wherein each of the sensor elements comprises a transition point control input, connected to a gate of the dedicated transistor.

10. The sensor device of claim 1, comprising a fabrication parameter memory and calibration means connected to the fablication parameter memory, for reducing fixed-pattern noise of the sensor elements by fabrication parameter based sensor calibration.

11. The sensor device of claim 1, wherein the array of sensor elements is formed as an integrated circuit in a plate-shaped silicon substrate which is bonded to a fibre-optic scintillating plate and to a PCB and encapsulated in a housing, to form a plate-shaped X-ray image sensor.

12. Use of a sensor device of claim 1, for medical imaging, in particular for dental imaging.

13. Use of claim 12, wherein sensor fabrication parameters which are stored independently and/or remotely from the sensor are used for sensor calibration which in particular reduces fixed pattern noise.

14. A method for reducing fixed pattern noise inherent to the sensor of claim 1, using a correction model based on the first gain, transition point characteristics and the second gain.
